(19) United States
(12) Patent Application Publication
(10) Pub. No.: US 2026/0033013 A1
(43) Pub. Date: Jan. 29, 2026

(54) SEMICONDUCTOR DEVICE HAVING ESD PROTECTION ELEMENT

(71) Applicant: MICRON TECHNOLOGY, INC., BOISE, ID (US)

(72) Inventors: Miho Matsui, Tokyo (JP); Takashi Ishihara, Tokyo (JP); Haruka Momota, Tokyo (JP)

(73) Assignee: MICRON TECHNOLOGY, INC., Boise, ID (US)

(21) Appl. No.: 19/266,021

(22) Filed: Jul. 10, 2025

Related U.S. Application Data
(60) Provisional application No. 63/676,153, filed on Jul. 26, 2024.

(51) Int. Cl. H10D 89/60; H10D 84/83

(52) U.S. Cl. CPC H10D 89/931; H10D 84/83; H10D 89/611

(57) ABSTRACT

An example apparatus includes a data terminal, a first power line supplied with a first voltage, a second power line supplied with a second voltage different from the first voltage, first and second transistors coupled in series between the first power line and the data terminal, a third transistor coupled between the second power line and the data terminal, and a first ESD protection element coupled between the first power line and a first internal node between the first and second transistors.

### CROSS-REFERENCE TO RELATED APPLICATIONS

This application claims the filing benefit of U.S. Provisional Application No. 63/676,153, filed Jul. 26, 2024. This application is incorporated by reference herein in its entirety and for all purposes.

### BACKGROUND

In a semiconductor device such as a DRAM, there is a case where decreasing parasitic capacitance of a data I/O terminal is required in order to improve the signal quality of read data and write data. As a method for decreasing parasitic capacitance of a data I/O terminal, there is conceived a method of downscaling the size of a protection diode used for ESD countermeasures. However, if downscaling of the size of a protection diode is merely made without any other measures, in an ESD test referred to as “CDM mode”, a large voltage is applied on an output transistor, so that there is a risk of breaking down a gate insulating film constituting the output transistor.

### BRIEF DESCRIPTION OF THE DRAWINGS

FIG. 1 is a block diagram showing a configuration of a semiconductor memory device according to an embodiment of the present disclosure;

FIG. 2 is a circuit diagram of a data I/O circuit;

FIGS. 3A and 3B are explanatory diagrams of a flow of a current in an ESD test;

FIGS. 4A to 4C are graphs for explaining I-V characteristics of transistors; and

FIGS. 5 and 6 are a circuit diagram of a data I/O circuit according to a modification and a circuit diagram of a data I/O circuit according to another modification, respectively.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

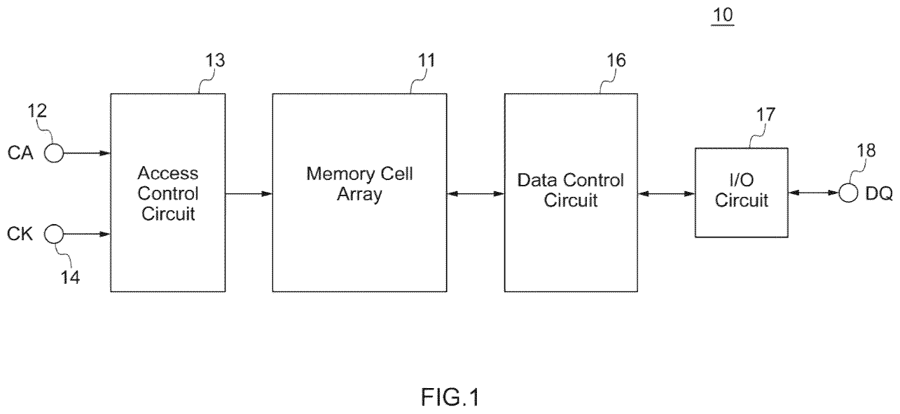

FIG. 1 is a block diagram showing a configuration of a semiconductor memory device 10 according to an embodiment of the present disclosure. The semiconductor memory device 10 shown in FIG. 1 is an LPDDR5 DRAM and includes a memory cell array 11. When access is made to the memory cell array 11, a command address signal CA is input from outside to a command address terminal 12. The command address signal CA is supplied to an access control circuit 13. The access control circuit 13 synchronizes with an external clock signal CK input to a clock terminal 14 so as to perform decoding of the command address signal CA and latency counting.

When a command included in the command address signal CA indicates a read operation, the access control circuit 13 performs read-accessing to a memory cell included in the memory cell array 11 based on an address included in the command address signal CA. Read data DQ read from the accessed memory cell is output to outside from a data I/O terminal 18 via a data control circuit 16 and a data I/O circuit 17. When the command included in the command address signal CA indicates a write operation, write data DQ having been input to the data I/O terminal 18 is transferred to the memory cell array 11 via the data I/O circuit 17 and the data control circuit 16. The write data DQ having been transferred to the memory cell array 11 is written in the memory cell included in the memory cell array 11 based on the address included in the command address signal CA.

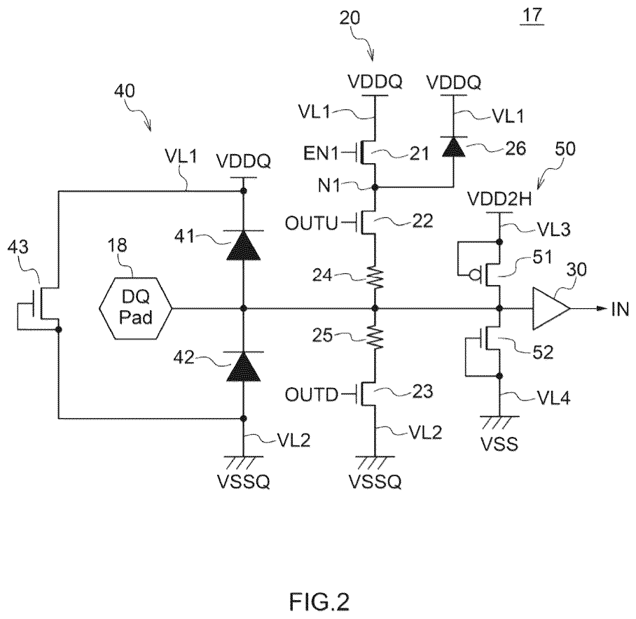

FIG. 2 is a circuit diagram of the data I/O circuit 17 and shows a circuit corresponding to one data I/O terminal 18. As shown in FIG. 2, the data I/O circuit 17 includes an output buffer 20, an input buffer 30, and ESD protection circuits 40 and 50.

The output buffer 20 includes N-channel MOS transistors 21 to 23, resistance elements 24 and 25, and an ESD protection diode 26. The transistors 21 and 22 and the resistance element 24 are connected to one another in series in this order between a power line VL1 to which a power potential VDDQ is supplied and the data I/O terminal 18. The resistance element 25 and the transistor 23 are connected to each other in series in this order between the data I/O terminal 18 and a power line VL2 to which a power potential VSSQ is supplied. The diode 26 has an anode connected to a coupling node N1 between the transistor 21 and the transistor 22 and a cathode connected to the power line VL1. It is permissible that the resistance value of the resistance element 24 is lower than the resistance value of the resistance element 25. As an example, the resistance value of the resistance element 24 is equal to or less than 200Ω and the resistance value of the resistance element 25 is equal to or more than 100Ω.

The transistor 21 is a cutoff transistor that reduces a leak current of the output buffer 20 at a time of deactivation and the film thickness of a gate insulating film of the transistor 21 is thicker than those of the transistors 22 and 23 in order to make the leak current of the output buffer 20 less when the transistor 21 is turned off. An enable signal EN1 is supplied to a gate electrode of the transistor 21. The transistor 22 is an output transistor that pulls up the data I/O terminal 18 and a pull-up signal OUTU is supplied to a gate electrode thereof. The transistor 23 is an output transistor that pulls down the data I/O terminal 18 and a pull-down signal OUTD is supplied to a gate electrode thereof. When high-level read data DQ is output from the data I/O terminal 18, the transistors 21 and 22 are turned on and the transistor 23 is turned off. When low-level read data DQ is output from the data I/O terminal 18, the transistors 21 and 23 are turned on and the transistor 22 is turned off.

The input buffer 30 has an input node connected to the data I/O terminal 18. Accordingly, write data DQ input to the data I/O terminal 18 at a time of a write operation is converted into internal write data IN by the input buffer 30 and the converted write data DQ is supplied to the data control circuit 16 shown in FIG. 1.

The ESD protection circuit 40 includes ESD protection diodes 41 to 43. The diode 41 has an anode connected to the data I/O terminal 18 and a cathode connected to the power line VL1. The diode 42 has a cathode connected to the data I/O terminal 18 and an anode connected to the power line VL2. The diode 43 has a cathode connected to the power line VL1 and an anode connected to the power line VL2. Meanwhile, since the diode 26 included in the output buffer 20 is connected to the coupling node N1, it has no contribution to parasitic capacitance of the data I/O terminal 18.

The ESD protection circuit 50 includes ESD protection diodes 51 and 52. The diode 51 is formed of a P-channel MOS transistor and has an anode connected to the data I/O terminal 18 and a cathode connected to a power line VL3. The diode 52 is formed of an N-channel MOS transistor and has a cathode connected to the data I/O terminal 18 and an anode connected to a power line VL4. The power line VL3 is a line to which a power potential VDD2H is supplied. The power line VL4 is a line to which a power potential VSS is supplied.

An ESD test referred to as “CDM mode” is conducted on the semiconductor memory device 10 before its shipment. The ESD test includes a first ESD test in which the data I/O terminal 18 is connected to a ground potential (GND) in a state where a whole chip is charged with a high potential (100V, for example) and a second ESD test in which the data I/O terminal 18 is connected to a ground potential (GND) in a state where a whole chip is charged with a negative potential (−100V, for example). In the first ESD test, a substantially whole chip except for the data I/O terminal 18 is charged with a high potential (100V, for example). Accordingly, the power lines VL1 to VL4 and gate electrodes of the transistors 21 to 23 are also charged with a high potential. In the second ESD test, a substantially whole chip except for the data I/O terminal 18 is charged with a negative potential (−100V, for example). Accordingly, the power lines VL1 to VL4 and gate electrodes of the transistors 21 to 23 are also charged with a negative potential.

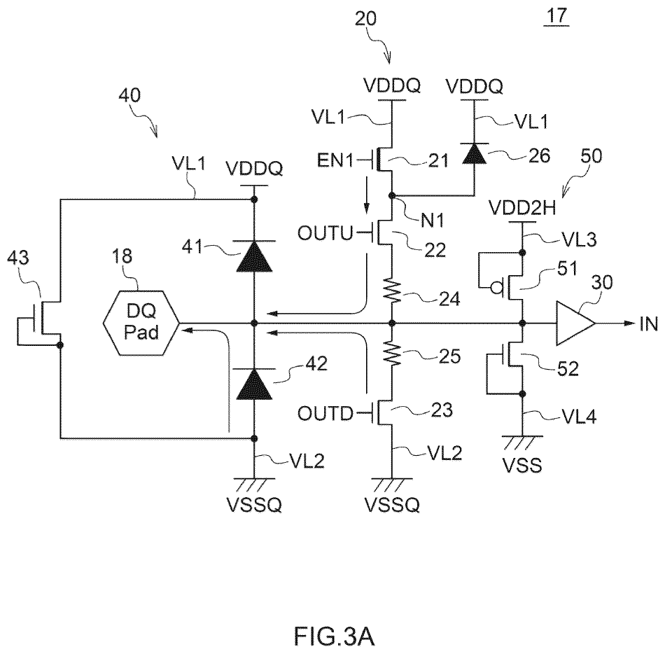

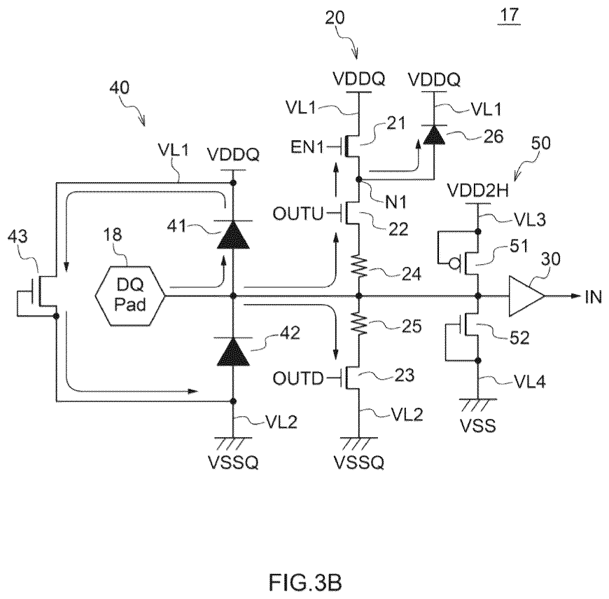

FIG. 3A is an explanatory diagram of a flow of a current in the first ESD test. As shown in FIG. 3A, when the first ESD test is conducted, a current flows from the power lines VL1 and VL2 to the data I/O terminal 18. Main current paths are a route via the diode 42, a route via the transistors 21 and 22 and the resistance element 24, and a route via the transistor 23 and the resistance element 25. In the route via the transistors 21 and 22 and the resistance element 24, since the resistance value of the transistor 21 is higher than the resistance value of the transistor 22, the voltage applied to the transistor 22 itself is not really high.

FIG. 3B is an explanatory diagram of a flow of a current in the second ESD test. As shown in FIG. 3B, when the second ESD test is conducted, a current flows from the data I/O terminal 18 to the power lines VL1 and VL2. Main current paths are a route via the diode 41, a route via the diodes 41 and 43, a route via the resistance element 24 and the transistor 22, and a route via the resistance element 25 and the transistor 23. Here, not only a route in which a current flows via the diode 41 to the power line VL1 is formed but also a route in which a current flows via the diodes 41 and 43 to the power line VL2 is formed because the power line VL2 has a resistance lower than that of the power line VL1. Further, when the resistance value of the resistance element 24 is lower than the resistance value of the resistance element 25, the quantity of current flowing in the route via the resistance element 24 and the transistor 22 is larger than the quantity of current flowing in the route via the resistance element 25 and the transistor 23.

Here, in the second ESD test, a current from the data I/O terminal 18 via the resistance element 24 and the transistor 22 flows to the power line VL1 through not only the route via the transistor 21 but also the route via the diode 26. Accordingly, a voltage generated between a source and a drain of the transistor 22 is relaxed.

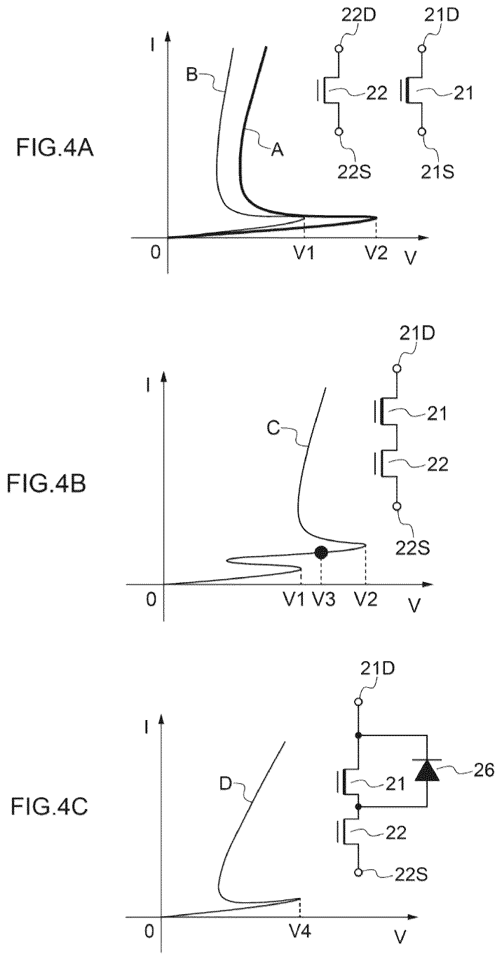

FIG. 4A to FIG. 4C are graphs for explaining I-V characteristics of the transistors 21 and 22. FIG. 4A shows I-V characteristics when each of the transistors 21 and 22 is a single body, where a characteristic A indicates a relation between a voltage applied between a source 21S and a drain 21D of the transistor 21 and a current flowing in the transistor 21 and a characteristic B indicates a relation between a voltage applied between a source 22S and a drain 22D of the transistor 22 and a current flowing in the transistor 22. As shown in FIG. 4A, when the voltage between the source 22S and the drain 22D of the transistor 22 exceeds a breakdown voltage V1, the voltage applied on the transistor 22 is sharply decreased and the current flowing in the transistor 22 is rapidly increased. Further, when the voltage between the source 21S and the drain 21D of the transistor 21 exceeds a breakdown voltage V2, the voltage applied on the transistor 21 is sharply decreased and the current flowing in the transistor 21 is rapidly increased. Here, since the film thickness of the gate insulating film of the transistor 21 is thicker than the film thickness of a gate insulating film of the transistor 22, the breakdown voltage V2 is higher than the breakdown voltage V1.

FIG. 4B shows I-V characteristics when the transistors 21 and 22 are connected to each other in series, where a characteristic C indicates a relation between a voltage applied between a source 22S of the transistor 22 and the drain 21D of the transistor 21 and a current flowing in the transistors 22 and 21. As shown in FIG. 4B, when the transistors 21 and 22 are connected to each other in series, breakdown of the transistor 22 is caused at the breakdown voltage V1 and breakdown of the transistor 21 is caused at the breakdown voltage V2. However, when the characteristic C reaches a breakdown voltage V3 that is between the breakdown voltage V1 and the breakdown voltage V2, there is a risk that the gate insulating film of the transistor 22 has insulation breakdown.

FIG. 4C shows I-V characteristics when the transistors 21 and 22 are connected to each other in series and the diode 26 is connected to the transistor 21 in parallel, where a characteristic D indicates a relation between a voltage applied between the source 22S of the transistor 22 and the drain 21D of the transistor 21 and a current flowing in the transistors 22 and 21 and the diode 26. As shown in FIG. 4C, when the diode 26 is connected in parallel to the transistor 21, breakdown of the transistor 22 is caused at a breakdown voltage V4, the voltage applied on the transistor 22 is sharply decreased, and the current flowing via the transistor 22 and the diode 26 is rapidly increased. The breakdown voltage V4 is a value obtained by adding a threshold voltage of the diode 26 to the breakdown voltage V1 of the transistor 22 itself, and the breakdown voltage V4 is sufficiently lower than the breakdown voltage V3 described with reference to FIG. 4B. Accordingly, in the second ESD test, the most part of current from the data I/O terminal 18 via the resistance element 24 and the transistor 22 flows via the diode 26 to the power line VL1.

With this mechanism, the semiconductor memory device 10 according to the present embodiment can prevent insulation breakdown of the transistor 22 in the second ESD test. In addition, as compared with a case where the diode 26 is not provided, the quantity of current flowing from the data I/O terminal 18 to the power line VL1 via the resistance element 24 and the transistor 22 becomes larger, thereby decreasing the current flowing via the diode 41. Accordingly, downscaling of the size of the diode 41 can also be achieved. As the size of the diode 41 is downscaled, parasitic capacitance of the data I/O terminal 18 is decreased, thereby improving the signal quality of the read data DQ and the write data DQ.

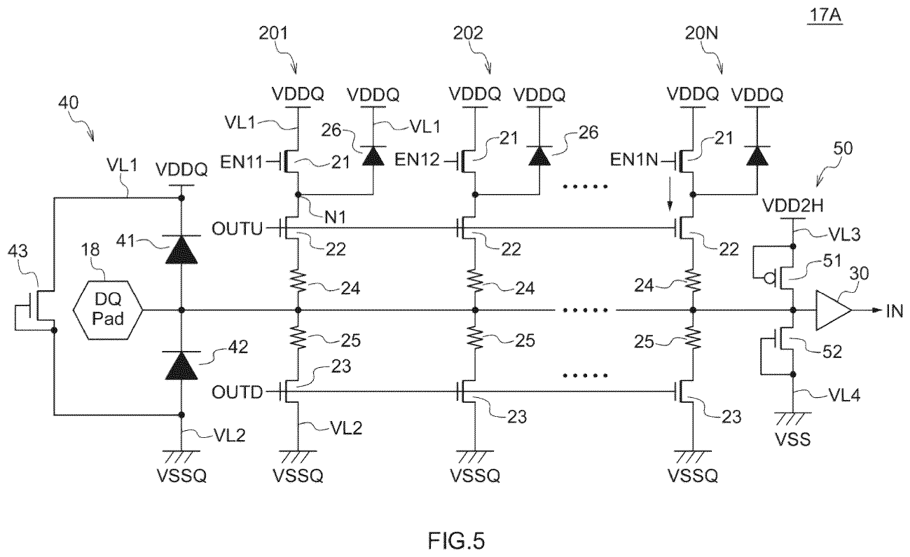

FIG. 5 is a circuit diagram of a data I/O circuit 17A according to a first modification. The data I/O circuit 17A shown in FIG. 5 is different from the data I/O circuit 17 shown in FIG. 2 in a feature that a plurality of output buffers 201 to 20N are provided in parallel to one data I/O terminal 18. While the output buffers 201 to 20N have mutually the same circuit configuration, enable signals EN11 to EN1N respectively corresponding to the output buffers 201 to 20N are supplied to the gate electrode of the transistor 21. Accordingly, it is possible to make the output impedance of the data I/O circuit 17 variable according to the number of the enable signals EN11 to EN1N to be activated. Also in this circuit configuration, by coupling the diode 26 to each of the output buffer 201 to 20N, it is possible to prevent insulation breakdown of the transistor 22 in the second ESD test.

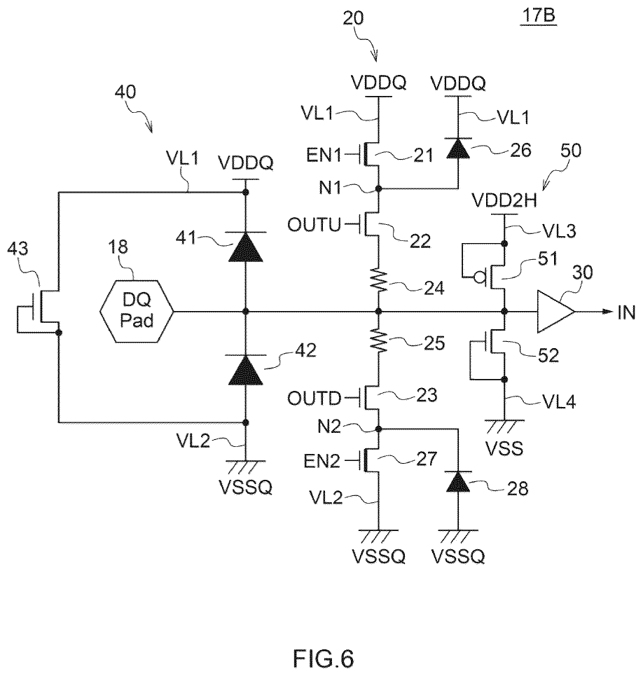

FIG. 6 is a circuit diagram of a data I/O circuit 17B according to a second modification. The data I/O circuit 17B shown in FIG. 6 is different from the data I/O circuit 17 shown in FIG. 2 in a feature that an N-channel MOS transistor 27 and a diode 28 are added to the output buffer 20. The resistance element 25 and the transistors 23 and 27 are connected to one another in series in this order between the data I/O terminal 18 and the power line VL2. The diode 28 has a cathode connected to a coupling node N2 between the transistor 23 and the transistor 27 and an anode connected to the power line VL2. The transistor 27 is a cutoff transistor that reduces a leak current of the output buffer 20 at a time of deactivation and the film thickness of a gate insulating film of the transistor 27 is thicker than those of the transistors 22 and 23 in order to make the leak current of the output buffer 20 less when the transistor 27 is turned off. The film thickness of the gate insulating film of the transistor 27 may be the same as the film thickness of the gate insulating film of the transistor 21. An enable signal EN2 is supplied to a gate electrode of the transistor 27. The enable signal EN2 may be the same signal as the enable signal EN1. With this circuit configuration, in the first ESD test, a current flowing from the power line VL2 to the data I/O terminal 18 via the diode 28 and the transistor 23 is increased, thereby enabling to downscale the size of the diode 42. As the size of the diode 42 is downscaled, parasitic capacitance of the data I/O terminal 18 is further decreased, thereby improving the signal quality of the read data DQ and the write data DQ even more.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a data terminal;
a first power line supplied with a first voltage;
a second power line supplied with a second voltage different from the first voltage;
first and second transistors coupled in series between the first power line and the data terminal;
a third transistor coupled between the second power line and the data terminal; and
a first ESD protection element coupled between the first power line and a first internal node between the first and second transistors.

2. The apparatus of claim 1, wherein the first ESD protection element includes a first diode.

3. The apparatus of claim 1, wherein the first, second and third transistors are same conductivity type transistors.

4. The apparatus of claim 3, wherein the first, second and third transistors are NMOS transistors.

5. The apparatus of claim 3,
wherein the first transistor is coupled between the first power line and the first internal node,
wherein the second transistor is coupled between the first internal node and the data terminal, and
wherein a gate insulating film of the first transistor is thicker than a gate insulating film of the second transistor.

6. The apparatus of claim 5, wherein the gate insulating film of the first transistor is thicker than a gate insulating film of the third transistor.

7. The apparatus of claim 5,
wherein the first transistor is configured to be controlled by a first enable signal,
wherein the second transistor is configured to be controlled by a first internal data signal and
wherein the data terminal is brought into a first logic level when both the first enable signal and the first internal data signal are activated.

8. The apparatus of claim 7,
wherein the third transistor is configured to be controlled by a second internal data signal, and
wherein the data terminal is brought into a second logic level when both the first enable signal and the second internal data signal are activated and the first internal data signal is deactivated.

9. The apparatus of claim 8, further comprising:
fourth and fifth transistors coupled in series between the first power line and the data terminal such that the fourth and fifth transistors are coupled in parallel with the first and second transistors;
a sixth transistor coupled between the second power line and the data terminal such that the sixth transistor is coupled in parallel with the third transistor; and
a second ESD protection element coupled between the first power line and a second internal node between the fourth and fifth transistor.

10. The apparatus of claim 9,
wherein the fourth transistor is configured to be controlled by a second enable signal,
wherein the fifth transistor is configured to be controlled by the first internal data signal, and
wherein the sixth transistor is configured to be controlled by the second internal data signal.

11. The apparatus of claim 5, further comprising:
a first resistor coupled between the second transistor and the data terminal; and
a second resistor coupled between the third transistor and the data terminal.

12. The apparatus of claim 11, wherein the first resistor is different in resistance value from the second resistor.

13. The apparatus of claim 1, further comprising:
a second ESD protection element coupled between the first power line and the data terminal; and
a third ESD protection element coupled between the second power line and the data terminal.

14. The apparatus of claim 13, further comprising a fourth ESD protection element coupled between the first power line and the second power line.

15. The apparatus of claim 1, further comprising an input buffer having an input node coupled to the data terminal.

16. The apparatus of claim 1, further comprising:
a fourth transistor coupled between the second power line and the third transistor; and
a second ESD protection element coupled between the second power line and a second internal node between the third and fourth transistor.

17. The apparatus of claim 1, wherein the first voltage is higher than the second voltage.

18. An apparatus comprising:
a data terminal; and
a data output driver coupled to the data terminal, the data output driver including first and second transistors coupled in series between a first power line and the data terminal and a diode coupled between the first power line and an internal node between the first and second transistors.

19. The apparatus of claim 18, wherein the first and second transistors are NMOS transistors and comprise first and second gate insulating films having different thickness, respectively.

20. An apparatus comprising:
a data terminal;
a first power line;
a first transistor coupled between the first power line and an internal node;
a second transistor coupled between the internal node and the data terminal; and
a diode having an anode coupled to the internal node and a cathode coupled to the first power line,
wherein a gate insulating film of the first transistor is thicker than a gate insulating film of the second transistor,
wherein the first transistor is configured to be controlled by an enable signal,
wherein the second transistor is configured to be controlled by a first internal data signal, and
wherein the data terminal is brought into a first logic level when both the enable signal and the first internal data signal are activated.
